(19) United States
(12) Patent Application Publication
(10) Pub. No.: US 2025/0167114 A1
(43) Pub. Date: May 22, 2025

(54) SEMICONDUCTOR DEVICE AND MEMORY SYSTEM

(71) Applicant: Kioxia Corporation, Tokyo (JP)

(72) Inventor: Yuta TSUBOUCHI, Tokyo (JP)

(73) Assignee: Kioxia Corporation, Tokyo (JP)

(21) Appl. No.: 18/804,482

(22) Filed: Aug. 14, 2024

(30) Foreign Application Priority Data
Nov. 20, 2023 (JP) 2023-196813

(51) Int. Cl. H01L 23/528; H01L 23/522

(52) U.S. Cl. CPC H01L 23/5283; H01L 23/5223; H01L 23/5228

(57) ABSTRACT

According to one embodiment, a semiconductor device includes a first substrate; a semiconductor chip provided in a first region of a first face of the first substrate; and a first structure provided in a second region of the first face, wherein the first substrate includes: wiring embedded in the first substrate; a first conductor coupled to the semiconductor chip and the wiring and exposed on the first face; and a second conductor coupled to the first conductor via the wiring and exposed on a second face of the first substrate, a height of the first structure in a first direction perpendicular to the first face is greater than a height of the semiconductor chip in the first direction, in a case where the first face is taken as a reference.

### CROSS-REFERENCE TO RELATED APPLICATIONS

This application is based upon and claims the benefit of priority from Japanese Patent Application No. 2023-196813, filed Nov. 20, 2023, the entire contents of which are incorporated herein by reference.

### FIELD

Embodiments described herein relate generally to a semiconductor device and a memory system.

### BACKGROUND

There is known a semiconductor device that can be mounted on a printed circuit board (PCB) or the like via a rewiring board. A semiconductor chip that constitutes an electronic component is mounted on the rewiring board.

### BRIEF DESCRIPTION OF THE DRAWINGS

FIG. 1 is a block diagram showing an example of a configuration of a storage system including a memory system according to an embodiment and a host device.

FIG. 2 is a perspective view showing an example of an appearance of a semiconductor device according to the embodiment.

FIG. 3 is a side view showing an example of the appearance of the semiconductor device that is mounted on a substrate in the memory system according to the embodiment.

FIG. 4 is a cross-sectional view showing an example of a cross-sectional structure of the semiconductor device according to the embodiment.

FIG. 5 is a perspective view showing an example of the appearance of a semiconductor device according to a modification.

### DETAILED DESCRIPTION

In general, according to one embodiment, a semiconductor device includes a first substrate; a semiconductor chip provided in a first region of a first face of the first substrate; and a first structure provided in a second region of the first face, wherein the first substrate includes: wiring embedded in the first substrate; a first conductor coupled to the semiconductor chip and the wiring and exposed on the first face; and a second conductor coupled to the first conductor via the wiring and exposed on a second face of the first substrate, a height of the first structure in a first direction perpendicular to the first face is greater than a height of the semiconductor chip in the first direction, in a case where the first face is taken as a reference.

Hereinafter, embodiments will be described with reference to the accompanying drawings. It should be noted that the dimensions, scales etc. of the drawings are not necessarily the same as those of actual products. In the description below, structural elements having substantially similar functions and configurations will be denoted by the same reference symbols.

### 1 Embodiment

A memory system according to the embodiment will be described.

### 1.1 Memory System

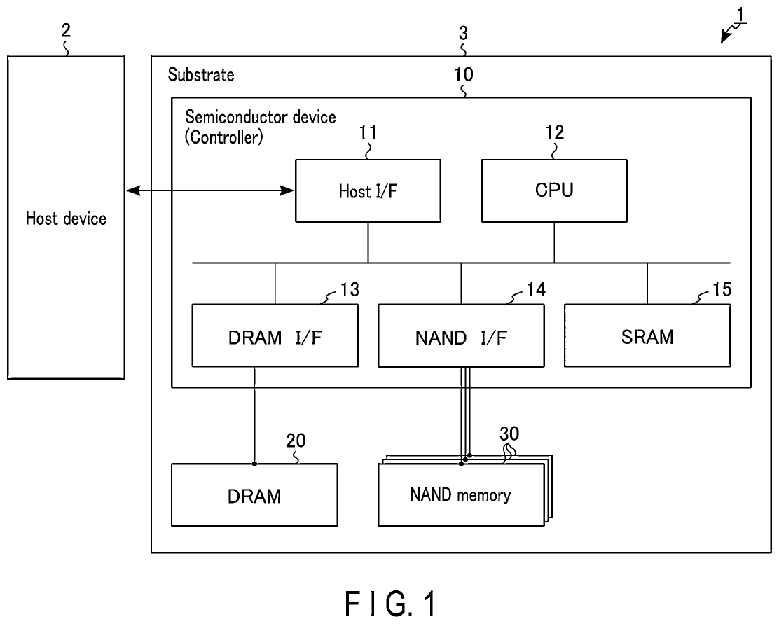

First, an example of a configuration of the memory system will be described with reference to FIG. 1. FIG. 1 is a block diagram showing an example of the configuration of a storage system including the memory system according to the embodiment and a host device.

The memory system 1 includes, for example, a substrate 3, a semiconductor device 10, a DRAM (Dynamic Random Access Memory) 20, and one or more NAND flash memories 30. In the description below, the NAND flash memory 30 will be referred to as a NAND memory 30 as well.

The memory system 1 is, for example, an SSD (solid state drive) or an SD™ card. The memory system 1 communicates with an external host device 2, for example. The memory system 1 stores data supplied from the host device 2. The memory system 1 reads out data to the host device 2.

The substrate 3 is, for example, a printed circuit board. For example, the semiconductor device 10, the DRAM 20, and the one or more NAND memories 30 are mounted on the substrate 3. The substrate 3 is an example of a second substrate.

The semiconductor device 10 is, for example, a controller for the NAND memory 30. The semiconductor device 10 will be hereinafter referred to as a controller 10 as well. The controller 10 is configured, for example, as such an integrated circuit as a system-on-a-chip (SoC). The controller 10 receives an instruction from the host device 2. The controller 10 causes the DRAM 20 and the NAND memory 30 to execute operations, based on instructions received from the host device 2, for example. A function of each portion of the controller 10 can be realized by dedicated hardware, a processor that executes a program (firmware), or a combination of these.

Although the semiconductor device 10 will be described as the controller for the NAND memory 30 in connection with the embodiment, this is not restrictive. The semiconductor device 10 may include, for example, at least one of a controller, a DRAM, and a NAND flash memory. In a case where the semiconductor device 10 includes the DRAM and the NAND flash memory, the DRAM 20 and the NAND memory 30 need not be mounted on the substrate 3.

The DRAM 20 is a volatile memory. It should be noted that the memory system 1 may include another type of volatile or nonvolatile memory in place of the DRAM 20. The DRAM 20 is configured to communicate with the controller 10. The DRAM 20 temporarily stores data read from the NAND memory 30 and write data received from the host device 2 by the controller 10.

The NAND memory 30 is a nonvolatile storage medium. It should be noted that the memory system 1 may include a nonvolatile storage medium other than a NAND type flash memory, in place of the NAND memory 30. The NAND memory 30 is configured to communicate with the controller 10. The NAND memory 30 stores data received from the host device 2 by the controller 10 in a nonvolatile manner. Also, the NAND memory 30 reads data stored in the nonvolatile manner and transmits it to the controller 10.

### 1.2 Functional Configuration of Memory Controller

The functional configuration of the controller 10 will be described with reference to FIG. 1.

The controller 10 includes a host I/F (host interface) 11, a CPU (processor) 12, a DRAM I/F (DRAM interface) 13, a NAND I/F (NAND interface) 14, and a SRAM (Static Random Access Memory) 15.

The host interface 11 performs communications between the controller 10 and the host device 2. The host interface 11 is configured such that it can transmit and receive differential serial signals, for example. The host interface 11 transfers commands and data received from the host device 2, for example, to the CPU 12 and the DRAM I/F 13.

The CPU 12 controls the operation of the entire controller 10. For example, the CPU 12 issues commands to instruct the NAND memory 30 to execute various operations, including a write operation, a read operation, and an erase operation.

The DRAM interface 13 is coupled to the DRAM 20. The DRAM interface 13 controls the DRAM 20. The DRAM interface 13 transmits and receives data to and from the DRAM 20 via a signal line.

The NAND interface 14 is coupled to the NAND memory 30. The NAND interface 14 controls the NAND memory 30. One NAND interface 14 can control a plurality of NAND memories 30. The NAND interface 14 transmits and receives data to and from the NAND memory 30 via a signal line. The NAND interface 14 transmits data (commands, addresses, write data, etc.) corresponding to a read operation, a write operation, an erase operation, etc., for example, to the NAND memory 30. Also, the NAND interface 14 receives read data from the NAND memory 30 during the read operation, for example.

The SRAM 15 is a volatile memory. It should be noted that the memory system 1 may include, in place of the SRAM 15, a memory having a faster access speed than the DRAM 20. The SRAM 15 is used as a work area of the CPU 12.

### 1.3 Structure of Semiconductor Device

Next, a description will be given of the structure of the semiconductor device 10.

### 1.3.1 Appearance

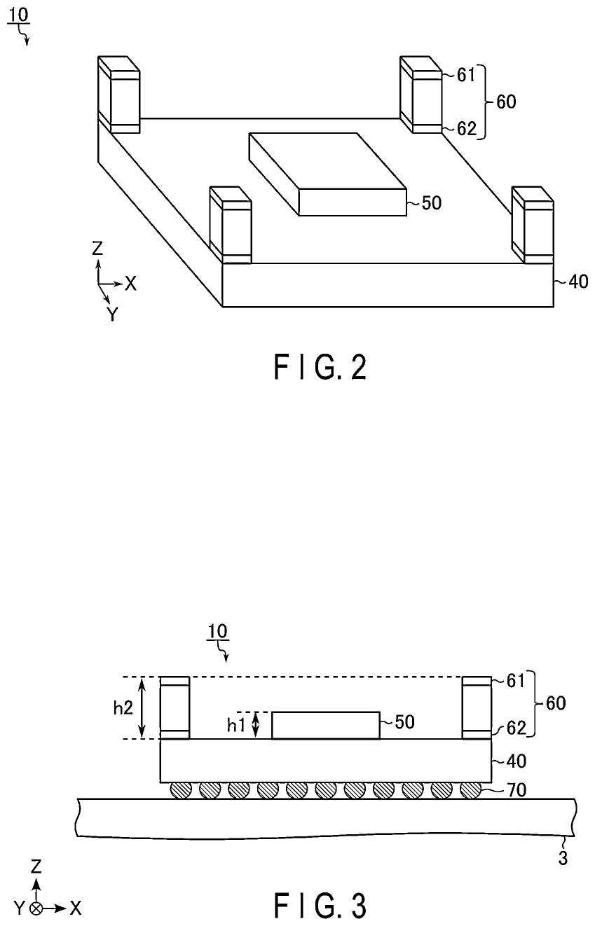

First, the appearance of the semiconductor device 10 according to the embodiment will be described with reference to FIG. 2 and FIG. 3. FIG. 2 is a perspective view showing an example of the appearance of the semiconductor device according to the embodiment. FIG. 3 is a side view showing an example of the appearance of the semiconductor device that is mounted on a substrate in the memory system according to the embodiment. FIG. 3 is a side view, viewed in a Y direction, showing an example of the semiconductor device 10 mounted on the substrate 3.

The semiconductor device 10 includes a rewiring board 40, a semiconductor chip 50, and one or more structures 60.

In the description below, the thickness direction of the rewiring board 40 is referred to as a Z direction or the vertical direction. In addition, in a case where a structural element of the semiconductor device 10 has two faces opposing each other in the vertical direction, these two faces are referred to as the upper face and the lower face, respectively. In addition, two directions perpendicular to each other in a plane perpendicular to the Z direction are referred to as an X direction and the Y direction.

The rewiring board 40 has a layered structure formed using rewiring technology. Wirings are embedded in the rewiring board 40. Although not shown in FIG. 2 or FIG. 3, the upper and lower faces of the rewiring board 40 are provided with electrodes that are coupled by the embedded wiring, as described below. The electrodes have exposed faces. The rewiring board 40 has, for example, a rectangular parallelepiped shape. The rewiring board 40 is an example of a first substrate.

A semiconductor chip 50 is provided on the upper face of the rewiring board 40. The upper face of the rewiring board 40 is referred to as a chip mounting face as well. The semiconductor chip 50 includes, for example, configurations of main electrical circuits of the semiconductor device 10. That is, the semiconductor chip 50 includes, for example, the controller 10 of the NAND memory 30. The electrodes provided on the lower face of the semiconductor chip 50 are electrically coupled to the electrodes provided on the upper face of the rewiring board 40. As shown in FIG. 3, the height of the semiconductor chip 50 in the Z direction is height h1 in a case where the upper face (chip mounting face) of the rewiring board 40 is taken as a reference. The semiconductor chip 50 has, for example, a rectangular parallelepiped shape.

One or more structures 60 are provided on the upper face of the rewiring board 40 except in a region where the semiconductor chip 50 is provided. In the embodiment, the semiconductor device 10 includes four structures 60, but this is not restrictive. The number of structures 60 can be one or more; it can range from one to three, or it can be five or more. In a case where the number of structures 60 is two or more, the plurality of structures 60 are provided as structures independent of each other. Each structure 60 has, for example, a columnar shape. However, the shape of the structures 60 is not limited to the columnar shape, and may be, for example, a pyramidal shape that becomes thinner as it moves away from the rewiring board 40. As shown in FIG. 3, the height of each structure 60 in the Z direction is height h2 in a case where the top face (chip mounting face) of the rewiring board 40 is taken as a reference. Height h2 is higher than height h1. One or more of the structures 60 are, for example, resin, ceramic, glass, or resistor. The resistor is, for example, a resistive element, a resistor device, or the like containing at least one of metal and silicon. In a case where the structure 60 is the resistor device, the structure 60 includes, for example, electrodes 61 and 62 opposing each other in the Z direction. Although not shown, the structure 60 is electrically coupled, for example, to an electrode that is one of electrodes provided on the upper face of the rewiring board 40 and that is electrically coupled to an electrode supplied with a ground potential or a power supply potential. In a case where the structure 60 is the resistor device, the electrode 62 is electrically coupled to the electrode supplied with the ground potential or the power supply potential. Although not shown, each structure 60 is arranged to be spaced apart from a signal wiring on the upper face of the rewiring board 40, as viewed in the Z direction, for example. In other words, each structure 60 is arranged at a position that does not overlap the signal wiring as viewed in the Z direction, for example.

It should be noted that one or more structures 60 are provided, for example, such that the semiconductor device 10 can stand independently when it is placed upside down on a flat face. Furthermore, the one or more structures 60 are provided such that when the semiconductor device 10 is placed upside down as described above, at least part of the semiconductor chip 50 does not come into contact with the flat face described above. It is therefore preferable to provide two or more structures 60.

As shown in FIG. 3, in the memory system 1, the semiconductor device 10 is mounted on the substrate 3 via a plurality of conductors 70 provided below the rewiring board 40. That is, the semiconductor device 10 is mounted on the substrate 3 by flip-chip bonding or by soldering. The plurality of conductors 70 are formed, for example, by bumps or by solder. Each of the plurality of conductors 70 is electrically coupled to an electrode provided on the lower face of the rewiring board 40.

### 1.3.2 Cross-Sectional Structure

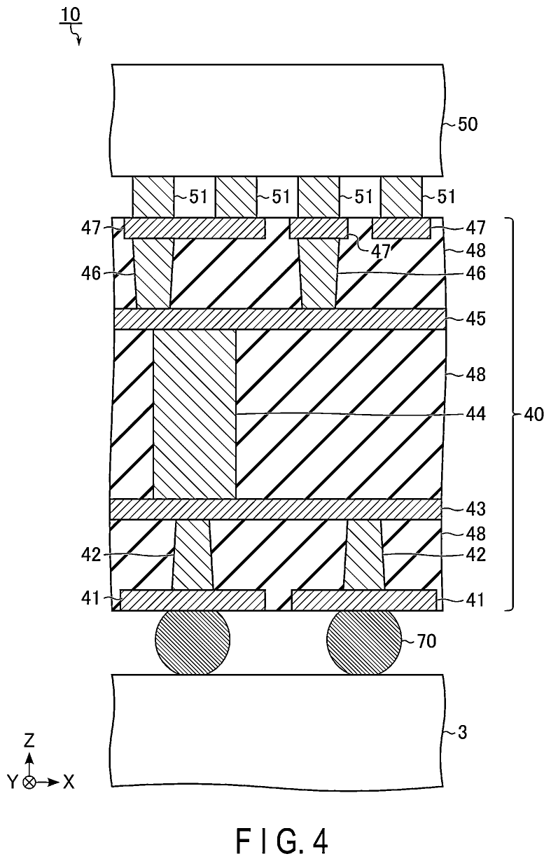

A further description will be given of the structure of the semiconductor device 10 according to the embodiment with reference to FIG. 4. FIG. 4 is a cross-sectional view showing an example of a cross-sectional structure of the semiconductor device according to the embodiment. In FIG. 4, the cross-sectional structure of a portion of the semiconductor device 10 in the XZ plane is shown together with portions of the conductor 70 and the substrate 3. The cross-sectional structure of the rewiring board 40 will be mainly described below.

The rewiring board 40 includes a plurality of conductor layers 41, 43, 45, and 47, a plurality of contact plugs 42, 44, and 46, and an insulator 48.

The plurality of conductor layers 41 are provided on the lower face of the rewiring board 40. Each of the plurality of conductor layers 41 includes a portion exposed on the lower face of the rewiring board 40. Each of the plurality of conductor layers 41 is coupled, for example, to a corresponding conductor 70 included among the plurality of conductors 70. The plurality of conductor layers 41 function as electrodes for electrically coupling the substrate 3 and the rewiring board 40 to each other via the plurality of conductors 70.

A plurality of contact plugs 42 are provided on the upper faces of the plurality of conductor layers 41. Each of the plurality of contact plugs 42 is coupled, for example, to a corresponding conductor layer 41 included among the plurality of conductor layers 41.

A plurality of conductor layers 43 are provided on the upper faces of the plurality of contact plugs 42. In FIG. 4, one conductor layer 43 that is included among the plurality of conductor layers 43 and that is coupled to two contact plugs 42 is shown.

A plurality of contact plugs 44 are provided on the upper faces of the plurality of conductor layers 43. In FIG. 4, one contact plug 44 that is included among the plurality of contact plugs 44 and that is coupled to the conductor layer 43 is shown.

A plurality of conductor layers 45 are provided on the upper faces of the contact plugs 44. In FIG. 4, one conductor layer 45 that is included among the plurality of conductor layers 45 and that is coupled to the contact plug 44 is shown.

A plurality of contact plugs 46 are provided on the upper face of the conductor layer 45. In FIG. 4, two contact plugs 46 that are included among the plurality of contact plugs 46 and that are coupled to the conductor layer 45 are shown.

A plurality of conductor layers 47 are provided on the upper faces of the plurality of contact plugs 46. Each of the plurality of conductor layers 47 is coupled to a corresponding contact plug 46 included among the plurality of contact plugs 46. Each of the plurality of conductor layers 47 includes a portion exposed on the upper face of the rewiring board 40. The plurality of conductor layers 47 function as electrodes for electrically coupling the rewiring board 40 and the semiconductor chip 50.

In the configuration including the plurality of conductor layers 41, 43, 45, and 47 and the plurality of contact plugs 42, 44, and 46 as described above, the plurality of conductor layers 43 and 45 and the plurality of contact plugs 42, 44, and 46 function as wirings embedded in the rewiring board 40. For example, these wirings electrically couple the plurality of conductor layers 41 and the plurality of conductor layers 47 together.

The insulator 48 is provided to protect the plurality of conductor layers 41, 43, 45, and 47, and the plurality of contact plugs 42, 44, and 46, except for the portions of the plurality of conductor layers 41 exposed on the lower face of the rewiring board 40 and the portions of the plurality of conductor layers 47 exposed on the upper face of the rewiring board 40.

In the memory system 1, a plurality of conductors 51 are provided between the rewiring board 40 and the semiconductor chip 50. The plurality of conductors 51 electrically couple the rewiring board 40 and the semiconductor chip 50 together. Each of the plurality of conductors 51 is coupled to a corresponding conductor layer 47 included among the plurality of conductor layers 47.

With the above-mentioned configuration, the semiconductor chip 50 and the substrate 3 are electrically coupled to each other via the rewiring board 40 and the plurality of conductors 51 and 70.

### 1.4 Advantageous Effects

According to the embodiment, the reliability of both the semiconductor device and the memory system can be improved. In what follows, the advantageous effects of the semiconductor device 10 and the memory system 1 according to the embodiment will be described.

The semiconductor device 10 according to the embodiment includes the rewiring board 40, the semiconductor chip 50 provided on the upper face of the rewiring board 40, and the structure 60 provided in a region of the upper face of the rewiring board 40 except for the region where the semiconductor chip 50 is provided. The rewiring board 40 includes the wirings embedded in the rewiring board 40, the conductor layer 47 electrically coupled to the semiconductor chip 50 and exposed on the upper face of the rewiring board 40, and the conductor layer 41 electrically coupled to the conductor layer 47 via wirings and exposed on the lower face of the rewiring board 40. In a case where the upper face of the rewiring board 40 is taken as a reference, the height h2 of the structure 60 in the Z direction is greater than the height h1 of the semiconductor chip 50 in the Z direction. The above-mentioned configuration can suppress electrostatic destruction of the semiconductor device 10 due to the charged device model (CDM).

Additionally, in a case where a semiconductor device is mounted on a substrate, a mounting robot grasps a semiconductor device placed on a tray, with the chip mounting face being the lower face of the rewiring board, for example. At this time, friction between the tray and the semiconductor device may cause charging of the semiconductor device. This may result in electrostatic destruction of the semiconductor device due to the CDM. According to the embodiment, the height h2 of the structure 60 is greater than the height h1 of the semiconductor chip 50, so that in comparison with a case where the structure 60 is not provided, the distance between the rewiring board 40 and the tray can be increased when the semiconductor device 10 is placed on the tray, with the chip mounting face being the lower face of the rewiring board 40. This enables suppression of an increase in the capacitance of the plate capacitor formed by the tray and the metal casing of the mounting robot for which the tray is arranged. Thus, electrostatic destruction due to the CDM can be suppressed. Therefore, the reliability of both the semiconductor device 10 and the memory system 1 can be improved.

Furthermore, the one or more structures 60 are provided such that when the semiconductor device 10 is placed upside down on a flat face parallel to the XY plane, the semiconductor chip 50 does not come into contact with that flat face. Even with this configuration, in a case where the semiconductor device is mounted on a substrate, it is possible to suppress an increase in the capacitance of the plate capacitor formed by the tray and the metal casing of the mounting robot for which the tray is arranged. In a case where the semiconductor device 10 includes a plurality of structures 60, the configuration described enables the semiconductor chip 50 to suppress an increase in the capacitance of the plate capacitor. Even through the above configurations, the reliability of both the semiconductor device 10 and the memory system 1 can be improved.

Each of the one or more structures 60 is arranged to be spaced apart, for example, from the signal wiring provided on the upper face of the rewiring board 40. With this configuration, interference between the structures 60 and the signal wiring can be suppressed. Therefore, the occurrence of signal loss is suppressed.

Each structure 60 is a resistive element or a resistor device. Each structure 60 is provided on the upper face of the rewiring board 40, and can be coupled to an electrode supplied with a ground potential or a power supply potential. With these configurations, a discharge path can be secured for the semiconductor device 10.

In addition, in the semiconductor device 10 according to the embodiment, the chip mounting face of the rewiring board 40 is not entirely covered by a mold. Thus, according to the embodiment, the heat dissipation performance of the semiconductor device 10 can be improved in comparison with a case where the chip mounting face of the rewiring board is entirely covered by the mold. Furthermore, the occurrence of signal loss due to the mold is suppressed in comparison with the case where the chip mounting face of the rewiring board is entirely covered by the mold.

### 2 Modification

The above-described embodiment can be modified in various ways. Modifications will be described below.

In connection with the above-described embodiment, reference was made to the case where each structure 60 is the resistive element or the resistor device, but this is not restrictive. Each structure 60 may be, for example, a capacitor.

A configuration of a memory system according to the modification can be similar to that of the memory system according to the embodiment. In what follows, a description will be given of configurations that distinguish the semiconductor device 10a according to the modification from the semiconductor device 10 according to the embodiment.

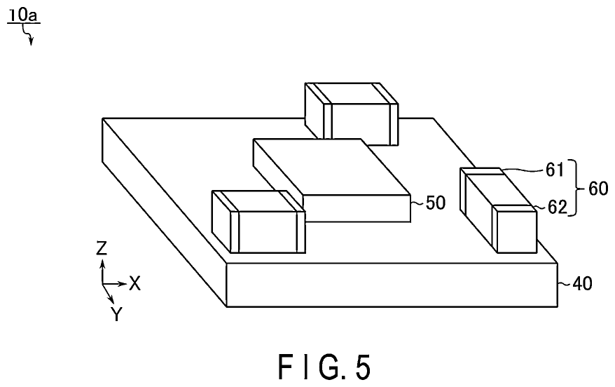

The structure of the semiconductor device 10a according to the modification will be described with reference to FIG. 5. FIG. 5 is a perspective view showing an example of the appearance of the semiconductor device according to the modification.

In the modification, each structure 60 is a capacitor. Electrodes 61 and 62 of each structure 60 are opposite to each other in a direction parallel to the XY plane, for example. FIG. 5 shows an example in which the electrodes 61 and 62 of each structure 60 are arranged in the X direction or in the Y direction. Although not shown in the drawings, on the upper face of the rewiring board 40, a plurality of conductor layers 47 include, for example, two different conductor layers 47 corresponding to either of the electrodes 61 and 62 of each structure 60. The electrodes 61 and 62 are electrically coupled to two different conductor layers 47. Thus, each structure 60 functions as a capacitor included in an electrical circuit provided in the semiconductor device 10a. As in the embodiment, each structure 60 is arranged such that it is spaced apart from the signal wiring provided on the upper face of the rewiring board 40 as viewed in the Z direction.

Although FIG. 5 shows the case in which the semiconductor device 10a includes three structures 60, the number of structures 60 can be one or more, as in the embodiment.

As in the embodiment, the above configuration can improve the reliability of both the semiconductor device 10a and the memory system 1.

### 3 Others

In connection with the above embodiment, reference was made to an example in which all the structures 60 are resistive elements or resistor devices, and in connection with the above modification, reference was made to an example in which all the structures 60 are capacitors, but these are not restrictive. The semiconductor device 10 of the embodiment may include a structure 60 functioning as a capacitor, and the semiconductor device 10a of the modification may include a structure 60 functioning as a resistor.

In addition, in each of the semiconductor devices 10 and 10a, the semiconductor chip 50 may be covered by a layered mold. That is, for example, in each of the embodiment and modification, the upper face and side face of the semiconductor chip 50 may be covered with a thin layered or film-like mold. In this case, the mold is provided in such a manner that it is spaced apart, for example, from the signal wiring on the upper face of the rewiring board 40 as viewed in the Z direction. That is, the above mold is provided so as not to overlap the signal wiring as viewed in the Z direction, for example. With this configuration, interference between the mold and the signal wiring can be suppressed. This suppresses the occurrence of signal loss.

In addition, in connection with the above-described embodiment and modification, reference was made to the case where the semiconductor chip 50 and one or more structures 60 are provided on the upper face of the rewiring board 40, but this is not restrictive. In addition to the semiconductor chip 50 and the one or more structures 60, other elements such as capacitors and resistors may be provided on the upper face of the rewiring board 40.

While certain embodiments have been described, these embodiments have been presented by way of example only, and are not intended to limit the scope of the inventions. Indeed, the novel devices and methods described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

1. A semiconductor device comprising:
a first substrate;
a semiconductor chip provided in a first region of a first face of the first substrate; and
a first structure provided in a second region of the first face,
wherein the first substrate includes:
wiring embedded in the first substrate;
a first conductor coupled to the semiconductor chip and the wiring and exposed on the first face; and
a second conductor coupled to the first conductor via the wiring and exposed on a second face of the first substrate,
a height of the first structure in a first direction perpendicular to the first face is greater than a height of the semiconductor chip in the first direction, in a case where the first face is taken as a reference.

2. The device of claim 1, wherein
in a case where the semiconductor device is placed on a third face, with the first face being a lower face of the first substrate, the semiconductor chip is not in contact with the third face.

3. The device of claim 1, further comprising:
a second structure provided in the second region independently of the first structure.

4. The device of claim 1, wherein
the first substrate further includes a third conductor exposed on the first face and supplied with a ground potential or a power supply potential; and
the first structure is a resistor and is coupled to the third conductor.

5. The device of claim 4, wherein
the first structure includes a first electrode and a second electrode that are aligned in the first direction, and
the first electrode is coupled to the third conductor.

6. The device of claim 1, wherein
the first substrate further includes a third conductor and a fourth conductor that are exposed on the first face and provided away from each other, and
the first structure is a capacitor provided between the third conductor and the fourth conductor.

7. The device of claim 6, wherein
the first structure includes a first electrode and a second electrode that are aligned in a second direction perpendicular to the first direction,
the first electrode is coupled to the third conductor, and
the second electrode is coupled to the fourth conductor.

8. The device of claim 1, wherein the second region is a region of the first face excluding the first region.

9. The device of claim 1, wherein the first structure includes resin, ceramic, or glass.

10. The device of claim 1, wherein the semiconductor chip includes a memory controller.

11. A memory system comprising:
the semiconductor device according to claim 10; and
a second substrate on which the semiconductor device is mounted.

12. The system of claim 11, wherein
in a case where the semiconductor device is placed on a third face, with the first face being a lower face of the first substrate, the semiconductor chip is not in contact with the third face.

13. The system of claim 11, further comprising:
a second structure provided in the second region independently of the first structure.

14. The system of claim 11, wherein
the first substrate further includes a third conductor exposed on the first face and supplied with a ground potential or a power supply potential; and
the first structure is a resistor and is coupled to the third conductor.

15. The system of claim 14, wherein
the first structure includes a first electrode and a second electrode that are aligned in the first direction, and
the first electrode is coupled to the third conductor.

16. The system of claim 11, wherein
the first substrate further includes a third conductor and a fourth conductor that are exposed on the first face and provided away from each other,
the first structure is a capacitor provided between the third conductor and the fourth conductor.

17. The system of claim 16, wherein
the first structure includes a first electrode and a second electrode that are aligned in a second direction perpendicular to the first direction,
the first electrode is coupled to the third conductor, and
the second electrode is coupled to the fourth conductor.

18. The system of claim 11, wherein the second region is a region of the first face excluding the first region.

19. The system of claim 11, wherein the first structure includes resin, ceramic, or glass.

20. The system of claim 11, wherein the semiconductor device is mounted on the second substrate by flip-chip bonding or soldering.
